(19) United States
(12) Patent Application Publication
(10) Pub. No.: US 2004/0211357 A1
(43) Pub. Date: Oct. 28, 2004

(54) Method of manufacturing a gap-filled structure of a semiconductor device

(76) Inventors: Pradad N. Gadgil, Santa Clara, CA (US); Shmuel Erez, San Jose, CA (US)

Correspondence Address: Prasad Gadgil, 301 Rosemont Drive, Santa Clara, CA, 95051, US

(21) Appl. No.: 10/422,760

(22) Filed: Apr. 24, 2003

(51) Int. Cl. C30B 23/00; C30B 25/00; C30B 28/12; C30B 28/14

(52) U.S. Cl. 117/84

(57) ABSTRACT

This invention relates to process sequence by atomic layer chemical vapor processing that includes thin film deposition for diffusion barriers in the vias, trenches or contact plug-holes followed by gap fill with ALD/CVD process and subsequent removal of the blanket film on the top by Atomic Layer Processing/Chemical Vapor Processing. The processes can be carried out in separate chambers or may be combined into one or more chambers. The apparatus employed in these processing steps allows the practitioner to rapidly complete process sequences of barrier deposition, gap fill and top layer planarization. In case of copper metallization scheme, ALD gap fill can be employed to replace electrochemical deposition of copper. Atomic layer removal of copper and other blanket films by gas phase reactions can replace the chemical-mechanical-polishing of the blanket films. Additional advantages of such processing scheme are elimination of defects, dishing, erosion, corrosion, liquid-electrolyte, slurry and other liquid waste. Benefit of such a process scheme is entrapment of the effluents and also precise metering and control of the injected amount to affect the chemical reaction in each step of the sequence that can lead to significant savings and higher chemical utilization efficiency.

### FIELD OF INVENTION

The present invention relates to thin film processing at a single atomic layer precision for manufacturing of semiconductor devices. More particularly, this invention describes a process sequence that can be performed in one or more atomic layer/chemical vapor processing reactors to enable processing of thin film materials at atomic level precision for microelectronic device fabrication. Furthermore, the process sequence as described herein is applicable to a variety of configurations for sub-micron devices such as thin film barrier deposition, gap fill for copper, aluminum and tungsten and their subsequent planarization to form metal plugs, shallow trench isolation and inter-metal dielectric among others.

### BACKGROUND OF THE INVENTION

Manufacturing of advanced integrated circuits (ICs) the microelectronic industry is accomplished through numerous and repetitive steps of deposition, patterning and etching of thin films on the surface of silicon wafer. An extremely complex, monolithic and three-dimensional structure with complex topography of variety of thin film materials such as semiconductors, insulators and metals is generated in an IC fabrication process.

The present trend in the ICs, which is going to continue in the foreseeable future, is to increase the wafer size and decrease the individual device dimensions. As an example, the silicon wafer size has progressed in recent years from 150 mm to 200 mm and now to 300 mm and the next wafer size of 400 mm is on the horizon. Simultaneously, the critical device dimension has decreased from 0.35 micron to 0.25 micron to 0.18 micron. Research and development for the future device dimension devices at 0.13 and next to 0.10-micron technologies is being conducted by several leading IC manufacturers. This in turn translates into extremely precise control of the critical process parameters such as film thickness, morphology, and conformal step coverage over complex topography and uniformity over an increasingly large area wafer surface.

Three dimensional device structures are fabricated on the surface of a silicon wafer through a repetitive sequence of deposition, patterning and etching of the layers in a precisely controlled manner. The etched portions of the wafer are filled with an appropriate conducting material on which the next layer is built by employing the same process sequence. The process sequence that forms at the back-end of the microelectronic devices where all the active devices on the silicon wafer are connected by conducting wiring of aluminum or copper is called dual damascene multi-level metallization scheme. Copper offers significant advantage due to its high electrical conductivity (˜2.0 micro-ohm/cm) as compared to aluminum (˜4.5 micro-ohm/cm) by reducing resistance to electrical current.

However, copper tends to diffuse in to the adjacent layers of a dielectric material during operation of the circuit under the influence of electrical potential and high temperatures generated due to large operational current densities. This can lead to short-circuiting two adjoining copper conductors and destruction of an active device. To avert this catastrophic end effect, but to retain the advantages copper can offer, it is clad in to a thin layer of diffusion resistant material called diffusion barrier.

In practice, first a dielectric layer is deposited on the planarized gate level dielectric containing tungsten contact plugs. Next, it is patterned and etched to open the direct electrical contacts to underlying tungsten. Subsequently, a thin (˜70-100 Å) diffusion barrier is deposited to arrest copper diffusion. The materials commonly employed as diffusion barriers are nitrides of transition metals such W, Ta, Ti and may contain their admixtures with silicon or carbon. A thin copper seed layer, approximately 5-10 nm, is then deposited by sputtering or Physical Vapor Deposition (PVD). Subsequently, the as deposited silicon wafer is transferred in to an electrochemical cell, containing a copper salt as an electrolyte, in which the wafer forms a planar cathode and a parallel copper plate forms an anode. The ensuing electrochemical reaction, under the application of electrical power, deposits copper in the etched portions on the wafer and helps fill them with copper metal. However, during electrochemical deposition, copper also deposits on the flat surface of the silicon wafer, between two adjacent contacts, which must be removed in order to have a conducting pattern before the next level of dielectric material is deposited. The excess copper removal is achieved by a variety of methods such as Chemical-Mechanical Polishing (CMP), reverse electrochemical dissolution of copper, Chemo-Electro-Mechanical Polishing (CEMP). In the end, a blanket layer of silicon nitride or silicon carbide is deposited to Etch Stop exposed copper plugs. These steps are repeated to build a multi-level metallization structure.

The process sequence described above thus entails three different methods of processing namely (a) physical vapor deposition or sputtering (b) electrochemical deposition and (c) chemical-mechanical (or chemo-electro-mechanical) removal of copper. Each of the steps must be performed in dedicated equipment sequentially. However the approach as outlined above has a number of serious pitfalls:

(1) Inadequate step coverage by sputtering of barrier in small vias and trenches: As the critical device dimensions reduce with each device generation, the vias and trenches are becoming increasingly smaller from 0.25 to 0.18 to 0.13 to 0.10 micron and below in their critical dimension. Sputtering (PVD) being a line of sight process leads to inadequate deposition of thin film material on the side-walls of the dielectrics. As a result, conformality of barrier deposition by this method is becoming increasingly inadequate with decreasing device dimensions. This has significant adverse impact on the quality of copper seed layer and subsequent copper gap fill process.

(2) Poor conformality and discontinuity of copper seed layer by sputtering: The thin copper seed layer as sputtered on the underlying diffusion barrier also shows inadequate degree of conformal deposition and at times spatial discontinuity and non-uniformities over the contours and surfaces of the structures. However, any discontinuity in this layer has serious consequences for the next step of electrochemical copper deposition because electrochemical deposition requires a physically continuous electrode. The reliability and quality of the device in terms of important functional parameters such as electromigration resistant can be seriously compromised if this step is not performed satisfactorily.

(3) Dishing and erosion in CMP: During CMP the wafer surface is polished by rotating and pressing it against a flexible pad on to which an aqueous slurry containing a chemically active agent (chlorides of iron etc.) and an abrasive powder (such as Ceria—CeO₂) is spread. The material to be polished is removed under a combined action of chemical reaction and mechanical force. The surface being polished usually results in to dishing with the material at the center being polished more as compared to the edge. Moreover, end point detection of the process is a difficult task and this leads to erosion and over polishing. Further to this, CMP may lead to micro-scratches, embedded undesirable solids and corrosive material residue on the surface. A thorough and proper clean with a deionized water is a highly essential to mitigate these issues.

(4) Corrosion due to wet electrochemistry: This is a very serious issue that is being actively investigated. The CMP or the other processes employed to remove copper such as dissolution of copper in acidic solutions, reverse anodic electro-dissolution are fraught with corrosion of copper. This may be a direct result of micro-quantities of trapped water within grains boundaries of copper. Copper is highly susceptible to oxidation when exposed to moist air at room temperature. However, copper wiring in microcircuits during operation, as it conducts electricity, may heat up significantly. This may result in to undesirable scenarios: it can generate high pressure localized steam that can rupture the structure violently or it can set up localized galvanic cells that can initiate corrosion of copper. Moreover, in-situ corrosion due photoelectrons has been another serious problem. All these issues have a significant and adverse impact on the yield, reliability and stability of a copper metallization interconnect scheme.

(5) Defects in copper by CMP and electrochemistry: Various sources of defect generation in copper such as pin-holes, craters and volcanoes are associated with wet processes and CMP that impart adverse effects on the microstructure and overall quality of copper being laid down in the microcircuits.

(6) Process Waste Remediation: All the wet processes (CMP, Electrochemical Deposition, Copper Dissolution) in copper metallization use highly pure and deionized water in large quantities. Deionized water must be continuously supplied in large quantities and it must be treated properly to conform to the local, existing environmental regulations before it is sent in to effluent stream. Moreover, large quantities of used chemical slurry must be contained and its remediation must be carried out according to guidelines. This adds to the expenses and can be a substantial part of the final cost and operation.

(7) Cost of multiple tools and spare hardware and process consumables: The metallization scheme, as outlined above, has four distinct process steps that require a separate process module each. It thus entails substantial operating costs to the owner that can reach several million dollars per module, per year in terms of expensive floor space, operation, maintenance, and process chemical consumption.

(8) Cost of consumables and maintenance: three distinct processes in copper metallization call for consumables such as slurry, pads, chemicals, copper electrodes, electrolyte baths, additives, systems to maintain additives and bath concentration, hardware and its wear and tear and maintenance. Thus the overall cost of ownership (CoO) including installation, facilities and operations and maintenance per tool can be substantial.

(9) Finally, transfer of wafers from one machine to the other and issues related to handling, buffering and scheduling within the fab are although amenable to practical solutions are nonetheless non-trivial.

In summary, the existing process equipment and their operation suffer from various drawbacks and issues that adversely impinge on the cost, reliability and device yield. Moreover, the current equipment as described above, may not be extendible for smaller device dimensions below 0.10 micron for upcoming device generations. Thus, there is a clear and urgent need for vapor phase processes for deposition, gap fill and top layer removal and related equipment to provide the following:

perfectly conformal step coverage of the diffusion barrier layer,

perfectly conformal and high speed copper deposition process to completely fill vias and trenches (the contacts) without voids or defects with excellent adhesion and electro-migration resistance,

high speed removal process for excess top layer material deposited during the gap fill to expose the filled material in contacts,

extendibility of the process and equipment for processing of increasingly larger diameter wafers with continuously decreasing device dimensions below 0.13 micron,

improved uniformity and better thickness control across the wafer

In view of the demands as listed above, Atomic Layer Chemical Vapor Deposition is the most suitable technique that can be employed effectively to reach the desired solution. Atomic Layer Chemical Vapor Deposition (ALCVD or merely ALD) is a simple variant of the industry prevalent technique of Chemical Vapor Deposition. It was invented in Finland in late 70s to deposit thin and uniform films of compound semiconductors such as Zinc Sulfide as described in the U.S. Pat. No. 4,058,430 by Suntola et al. There are several attributes of ALD that make it an extremely attractive and highly desirable technique for its application to microelectronic industry. ALD is a flux independent technique and it is based on the principle of monolayer formation by chemisorption, which is self-limiting. ALD process is also relatively temperature uniformity insensitive. In a typical ALD sequence two highly reactive gases are injected sequentially on the substrate interspersed by an inert gas to sweep away excess reactants. A monolayer of the solid film is formed in each cycle and reaction by-products are swept away. The desired film is thickness is built by simply repeating the complete reaction sequence. The most desirable attribute of ALD is its ability to offer atomically uniform, perfectly conformal and area independent thin film coatings. With continuously decreasing device dimensions, such features in ALD make the application of ALD highly suitable and desirable for several future device generations and for a number of future larger wafer diameters. An excellent description of the fundamentals and applications of ALD and the progress it has made so far is offered in a review article written by T. Suntola titled Atomic Layer Epitaxy in the Handbook of Thin Film Process Technology, Part B 1.5, p. 1-17, IOP Publishing Limited, 1995, which is included herein for reference.

In ALD, however, the rate of deposition is fixed and it is solely dependent upon the speed of completion of a single ALD sequence, which is generally between 0.1 to 0.3 nm/cycle depending upon the dimensions of the monolayer. For ALD to become acceptable to the microelectronic industry it must offer competitive throughput. Hence, it is imperative to complete one ALD sequence comprising of four gas pulses in as short time as possible to be able to process thicker films. Furthermore, with the advent of low-k dielectric materials with polymeric composition, higher process temperatures have become unacceptable for material stability. This has led to inclusion of radical assisted ALD processes and reactor design as described in the U.S. Pat. No. 6,342,277 by Sherman and plasma assisted ALD process and reactor design in the U.S. Pat. No. 6,416,822 by Chiang et al.

In practice, however, the prevalent CVD or Plasma Enhanced CVD reactors cannot be effectively used as ALD reactors since efficient ALD process requires rapid completion of pulses along with physical separation of reactant streams. Such an operational characteristic can result in to restricting application of ALD for thin films such as diffusion barrier by ALD. It is thus highly desirable to employ a flexible ALD reactor that can process the thin films at lower temperatures than corresponding CVD processes and the one that can also modulate the processes within the single reactor from discrete or pulse flow to continuous, high rate CVD type, seamlessly. Such an ALD reactor can offer practicable application to the gap fill process, due its high rate of processing, in which the gaps being filled are in the range of 1000-2000 Å or so in lateral dimension. Larger gaps may also be satisfactorily filled, however, it may require longer processing time or the reactor may be operated in a continuous flow mode as in CVD processes. As an example, an Atomic Layer Processing reactor and its operation that satisfies the constraints described above is described in detail by the inventors as the present application in the U.S. patent application Ser. No. 10/019,244 filed May 20^{th}, 2002; the U.S. patent application Ser. No. 10/288,345 filed Nov. 4^{th}, 2002 and in the US Patent Application filed on Feb. 21, 2003 (2774P).

U.S. Pat. No. 6,368,954 issued to Lopatin et al. describes the application of ALD in the fabrication process of copper interconnects. A pre-seed layer and a thicker seed layer, both of copper, follow deposition of the diffusion barrier layer. The patent describes the process of formation of diffusion barrier layer and subsequent copper seed layer, both by ALD processes in the same reactor. The patent also recommends that reactor be purged with N₂ between two ALD processes for almost 15 minutes to an hour. There are several serious drawbacks in such an approach. First, the chemical composition of diffusion barrier and copper are substantially different and to avoid cross contamination, it is highly advisable to perform respective chemical processes for different thin film materials in dedicated reactors. Second, purge by dry nitrogen for long durations can slow the overall process sequence and make it uneconomical. Also, the patent states two step copper deposition process—pre seed layer and seed layer. Moreover, the inventors also state that the copper seed layer can be substantially thicker than the barrier layer and for very narrow trenches it may serve to form the interconnect itself and no further electrolytic deposition may be needed although, subsequent CMP step is essential. However, this can be practical only in case of very narrow features where the rate of ALD processes is sufficient to offer economical throughput. The current ALD equipment, as described before, is inadequate to process thicker films. Moreover, the choice of chemical reagent for copper removal is limited to a volatile liquid 1,1,1,5,5,5-Hexafluoro-2,4 pentanedione (H⁺hfac), only. Also, the patent states that electrochemical deposition (ECD) to fill the etched vias and trenches with solid copper and CMP is required to remove the excess copper film deposited on the top surface.

U.S. Pat. No. 6,482,740 issued to Soininen et al. discloses the deposition of metallic copper for interconnects in vias and trenches by reduction of copper oxide by various organic reagents such as alcohols, aldehydes and carbooxalic acids. However, this patent does not disclose application of ALD other than copper seed layer deposition. Moreover, it employs aqueous solutions of these reagents, which make copper susceptible to oxidation.

U.S. Pat. No. 6,284,052 issued to Nguyen et al. describes the removal of copper that is deposited on the internal reactor surfaces, especially on the heated wafer chuck, by oxidizing it first with oxygen plasma and then reacting it in-situ with a liquid chelating agent such as 1,1,1,5,5,5-Hexafluoro-2,4 pentanedione (H⁺hfac) to form a volatile solid compound copper (II)(hfac)₂ that is removed from the reactor under the action of vacuum and elevated temperature. There are several drawbacks in this scheme. First, active oxygen plasma is used to fully oxidize deposited metallic copper in to copper oxide and subsequent conversion of copper oxide to a volatile chelate. Full conversion of metallic copper in to copper oxide can lead to poor adhesion with internal surfaces of the reactor and result in to particulate formation. Also, the process chemistry is limited to copper oxide only, with oxygen and chelating agent being injected in series. Moreover, the copper removal process is carried out only when the substrate wafer is not present on the wafer holding chuck or pedestal. Having a substrate wafer with a large number of integrated circuits fabricated on it with conducting copper exposed to active plasma can be potentially detrimental to the integrated circuitry because of ion-induced damage.

Chiang et al., in a paper published the Journal of Vacuum Science and Technology, volume A 15, September-October 1997, p. 2677-2686, employed hydrogen atoms from microwave discharge to reduce carbon content from copper thin films deposited by Ion-induced CVD method. In such a method, direct impact collision of high-energy electrons and ions led to fragmentation of the copper hexa-fluoro-acetylacetonate vinyltrimethylsilane, [Cu(I)hfactvms] which was used as a copper precursor. It is thus highly desirable to eliminate such energetic species from the gas phase in order to avert undesirable fragmentation of the organometallic precursor, which leads to significant inclusion of impurities in the final product.

It is thus apparent to an individual skilled in the art that a high-speed Atomic Layer Processing reactor employed to facilitate processing of various thin films is a generic one in nature and is thus not limited by the reaction chemistry of deposition or etching or surface modification of any desired film material. Therefore, it has a secondary purpose to process, using one or more embodiments described herein, a variety of thin films of metals, semiconductors and insulators and suitable combinations thereof with atomic level precision on a substrate under suitable process conditions. To an individual skilled in the art, the objectives and advantages of the present invention will soon become apparent from the summary, detail description of the invention and specific embodiments described hereinafter. It should be understood, however, that the detail description of the invention and specific embodiments are given by way of illustration only, since various modifications and combinations of specific features of one or more embodiments are well within the scope and spirit of the present invention. In summary, the foregoing description indicates that there is a clear and urgent need to device a scheme that will simplify processing sequence, improve the quality of thin films and also enhance their reliability and yield with continuous critical dimension reduction.

### SUMMARY OF THE INVENTION

In accordance with the above stated constraints and features of the ALD process and objectives of the invention, the present invention has a primary purpose to further exploit and broaden the capabilities of the high rate ALD reactor to a high rate Atomic Layer Processing (ALP) reactor thereby bringing within its ambit additional processes such as layer-by-layer removal (isotropic etching) or layer-by-layer surface modification by vapor phase processes, either in a cyclic mode or in a continuous flow mode. Thus within the scope of this invention, ALP is defined the set of processes that include Atomic Later Deposition (ALD) and Atomic Layer Removal (ALR). Similarly, Chemical Vapor Processing is defined as set of processes that include Chemical Vapor Deposition (CVD) and also Chemical Vapor Removal (CVR) which operates in a continuous flow regime as opposed to a pulsed flow regime as employed in ALP.

The technique of ALP is suitably applied to substantially simplify copper metallization process sequence by modulating the rate of processing in either discrete pulse flow or continuous flow mode. Combination of appropriate vapor phase reaction chemistries, with or without plasma, with the gas flow modulation is used to preserve the necessary and beneficial aspects of the microelectronic device geometry. The present invention describes the process sequence starting with a diffusion barrier deposition, on the etched surface of a dielectric layer, by Atomic Layer Deposition process to obtain a highly conformal coating of the diffusion barrier layer of controlled thickness in the first substrate wafer-processing reactor.

In the next step, the substrate wafer is removed and placed in the second high-speed Atomic Layer Processing reactor and copper is deposited by employing either a discrete flow—sequential pulsing of gas flows—process or a continuous flow CVD type process or a suitable combination of both. As Atomic Layer Process fills a feature on the substrate wafer in highly conformal manner, a thin film equal in thickness deposited on the vertical walls of the feature is deposited on the top surface of the substrate in each step. As the feature, which has an almost perfectly perpendicular wall to the substrate surface, is filled in conformal fashion by an atomic layer deposition process, depositing layers on the sidewalls of the feature merge around the centerline fully plugging the gap. As a result, a planar copper film equivalent to one-half of the gap thickness is deposited on the top surface of the substrate. It should be noted here that the atomic layer-processing reactor is so designed as to modulate the processing rate over a wide range. In doing so, it can also operate as a continuous flow chemical vapor processing reactor that can achieve significantly higher rates of processing than that in a pulsed flow atomic layer processes.

Subsequently, the atomic-layer-processing reactor, in which copper was deposited, is purged completely. Next, the planar copper film on the top surface of the substrate is removed in-situ (without removing the substrate wafer) by employing suitable gaseous chemistries that are largely isotropic in nature thus leaving behind uniform flat surface with vertically filled solid copper plugs or interconnects, with an underlying diffusion barrier layer exposed on flat surface, in the same reactor. In order to accelerate the rate of copper removal reaction, temperature of the substrate wafer and the reactor walls is raised to the suitable level. The gap-fill deposition and isotropic removal processes are thus carried out in the same reactor without removing the substrate wafer from the reactor. In the first step, the copper surface is chemically converted in to an intermediate state such as oxide or halide by employing a suitable reagent and in the next step, the as converted copper surface is reacted with a chelating agent transported in to the reactor in vapor phase to generate a volatile copper chelate which is removed from the vicinity of the substrate wafer surface under the combined action of temperature and vacuum. This also results in to simultaneous cleaning of undesired deposition of copper on the inner surfaces of the deposition reactor. As a result, the deposition reactor continually operates in a quasi-clean state for the next substrate wafer to be processed. For this process, the reactor can also be operated in a continuous flow regime to process larger dimensions features economically.

Subsequent to complete removal of copper layers on the flat surface, the substrate is transferred to the first diffusion barrier deposition reactor and the reactor is completely purged and evacuated. Next, a suitable vapor-phase isotropic barrier etching chemistry is employed either in discrete flow—gas pulse mode or continuous flow mode to remove the remaining exposed barrier on the top substrate surface. The reaction products of the chemical reaction are volatile compounds of the constituents of the copper diffusion barrier layer, which are removed under the combined action of temperature and/or vacuum from the vicinity of the substrate wafer. Since the isotropic diffusion barrier removal process removes the same amount of material thickness as it was deposited in the first step of the barrier deposition process, it helps run diffusion barrier reactor in a quasi-clean state.

Finally, the substrate is transferred to a third dedicated Atomic Layer Vapor Processing reactor to be capped with the top protective cum etch-stop layer for copper features embedded in the wafer surface on which the next layer of dielectric material is deposited.

The end point for copper and diffusion barrier removal processes described above can be suitably detected by simply relying on the ratio of the blanket, exposed surface area of the substrate wafer to the sum of plug or interconnect area and the fact that the magnitude of the signal used by a detection instrument is proportional to the exposed area. For example, in copper removal process, the blanket copper film area is substantially larger than the sum total of the plug or interconnects area. As the final blanket copper layer on the top surface of the substrate is removed, only a small fraction of the copper surface is exposed and the signal intensity suddenly drops. As an example of end point detection instrument, a downstream residual gas analyzer may be suitably employed to detect the quantity of copper in vapor phase as function of time. Furthermore, dedicated reactors are employed to perform only one type of process chemistry, e.g. either copper, diffusion barrier or etch stop layer, whereby maintaining the purity of the internal environment and avoiding any cross contamination of elements from one layer in to the other. Also, such approach can become effective by multiple reactors being clustered around a single automated substrate handler for efficient process sequence integration and execution. Finally, wherein a particular process step, e.g. copper deposition and removal, within the overall process sequence is substantially longer than the other processes, multiple, identical reactors for that particular process chemistry can be employed and clustered to avoid a bottleneck or backlog in substrate transfer within the cluster of multiple reactors to realize maximum throughput.

### BRIEF DESCRIPTION OF THE DRAWINGS

FIG. 1 illustrates the magnified cross section view of the top portion of a substrate wafer, with a dual damascene structure, with part of the dielectric layer removed for copper diffusion barrier deposition in the multilevel metallization scheme according the prior art.

FIG. 2 shows the sequence of processes and equipment required to form copper metallization interconnect structures, with dual damascene structure, on the substrate wafer as practiced in the industry.

FIG. 3 illustrates the magnified cross section view of top the portion of a substrate wafer with dual damascene structure, after copper diffusion barrier deposition on the surface of the etched dielectric layer in accordance with the prior art.

FIG. 4 illustrates the schematic of an atomic layer chemical vapor processing apparatus.

FIG. 5 shows the magnified cross section view of the top portion of a substrate wafer with a dual damascene structure, after copper diffusion barrier deposition on the surface of the etched dielectric layer according to the atomic layer processes described in the present invention.

FIG. 6 shows the magnified cross section view of the top portion of a substrate wafer with a dual damascene structure, after copper diffusion barrier deposition and initial stages of copper deposition by processes described in the present invention.

FIG. 7 illustrates the magnified view of the cross section of the top portion of the substrate wafer with a dual damascene structure, after copper diffusion barrier deposition and during copper deposition by processes described in the present invention after completely filling the via of width d.

FIG. 8 shows the magnified view of the cross section of the top portion of the substrate wafer with a dual damascene structure, after diffusion barrier deposition and complete copper gap fill of the via and trench accomplished by the processes described in the present invention.

FIG. 9 shows the change in magnitude of the signal of a detection instrument used to detect the end of the process for removal of a layer.

FIG. 10 illustrates the magnified view of the cross section of the top portion of the substrate wafer with a dual damascene structure, after diffusion barrier deposition, complete copper gap fill of the via and trench and excess top copper layer removal process exposing the filled copper structures and blanket barrier according to the present invention.

FIG. 11 shows the magnified view of the cross section of the top portion of the substrate wafer with a dual damascene structure, after diffusion barrier deposition, copper gap fill, excess top copper layer removal and complete top copper diffusion barrier removal process according to the present invention.

FIG. 12 illustrates the magnified view of the cross section of the top portion of the substrate wafer after diffusion barrier deposition, copper gap fill, excess top copper layer removal, top copper diffusion barrier removal and etch stop layer deposition process according to the present invention.

FIG. 13 is a flow chart of the process sequence and substrate wafer transfer procedures within the multi-reactor cluster tool during complete processing of one level of copper interconnect metallization.

FIG. 14 illustrates the schematic of the cluster tool as described in FIG. 13, with central robotic handler to transfer substrate wafer, with three separate process reactors for the process sequence.

### DETAILED DESCRIPTION OF INVENTION

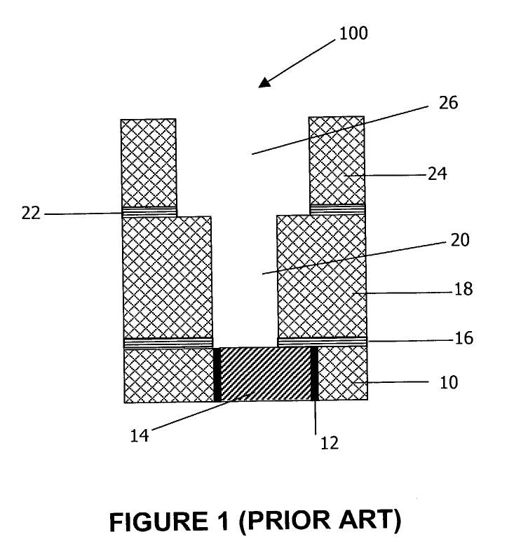

A magnified view of the cross section of the top portion of the substrate wafer with an etched dual damascene interconnect pattern 100 is shown in FIG. 1. The dual damascene pattern 100 comprises a previous dielectric layer 10, e.g. SiO₂, a diffusion barrier layer 12 for example TaN, a previous metallization layer 14 for example copper, a via etch stop layer 16, e.g. SiNₓ, via level dielectric layer 18, e.g. SiO₂, an open via gap 20, trench etch stop layer 22, e.g. SiNₓ and a trench level dielectric 24, e.g. SiO₂ and an open trench 26. To an individual skilled in the art, the dual damascene structure and its fabrication process are well known. The previous level of interconnect structure formed below the top dual damascene structure consists of a dielectric layer 10; a diffusion barrier layer 12 and the metallization layer 14 all can be formed by the same processes disclosed in this invention.

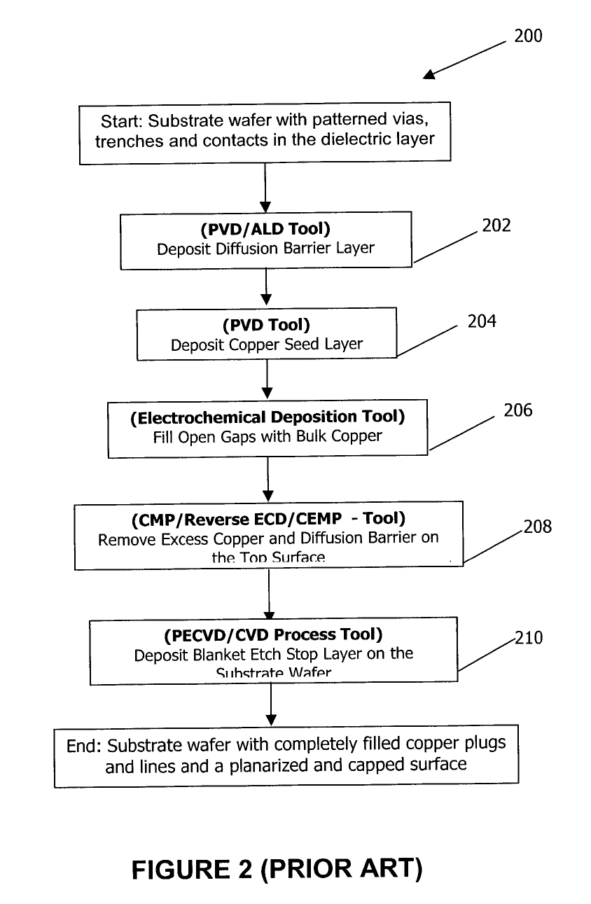

FIG. 2 describes the process sequence as practiced in the industry currently to fabricate dual damascene metallization structure. It starts with the substrate wafer with dual damascene interconnect pattern 100 etched on it. In step 202, the substrate wafer is transferred in to the physical vapor deposition tool to deposit thin copper diffusion barrier layer e.g. TaN on the surface of the dielectric layer. The nominal thickness of the barrier layer is approximately 5-10 nm. Next, in step 204 the substrate wafer is transferred to another PVD reactor to deposit a thin layer of copper with a nominal thickness of 5-10 nm. Subsequently, in step 206, the substrate wafer is transferred to the electrochemical deposition tool to fill the opening 100 completely. Next, in step 208, the substrate wafer is transferred to the Chemo-Mechanical Polishing (CMP) tool to remove the excess copper deposited during step 206 and the top layer of the diffusion barrier deposited in step 202. In the end, in step 210, an etch stop or a protective cap layer is deposited by either chemical vapor deposition or plasma enhanced chemical vapor deposition process and the substrate wafer is sent out for further processing.

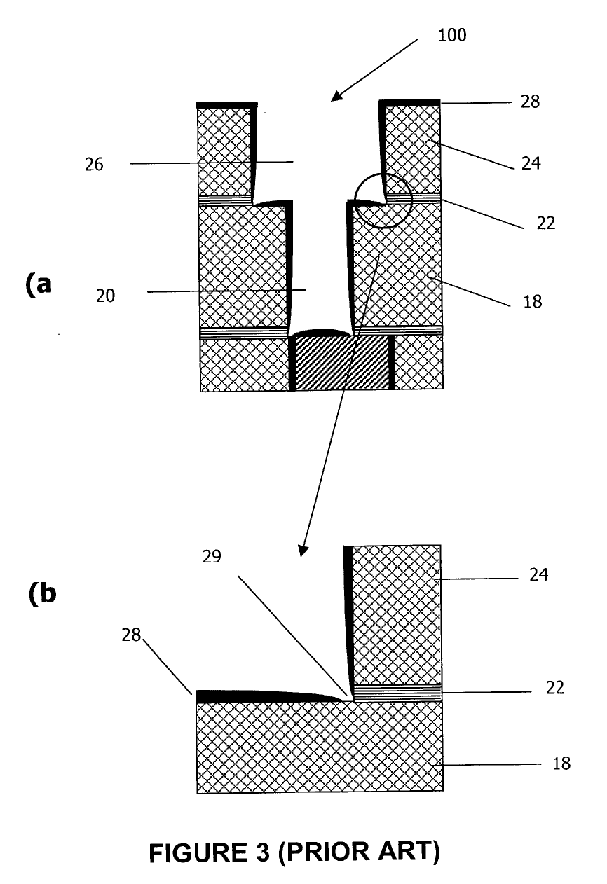

FIG. 3A shows magnified view of the cross section of the dual damascene interconnect structure 100, with as deposited copper diffusion barrier layer 28 on the inner surface of the via 20 and trench 26 by processes being currently practiced such as sputtering or PVD, which are line of sight processes. FIG. 3B shows a further magnified view of a corner section of the dual damascene structure, which clearly indicates highly uneven deposition of the diffusion barrier layer on the vertical surfaces and uncoated surfaces 29 in the vicinity of the corner that is highly detrimental for the functioning of the device.

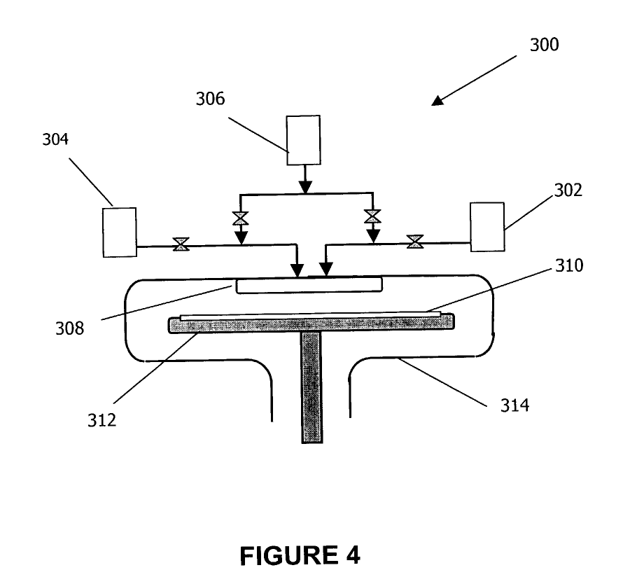

FIG. 4 shows schematic of an ALD reactor 300. It is supplied with two reactant supply sources 302 and 304 respectively with an inert gas supply source 306 connected to the gas injection assembly 308 through a number of switching valves. The gas injection assembly employed to spread the reactive gases from sources 302 and 304 and the inert gas from source 306 on to the surface of the substrate wafer 310 that is mounted on to and is supported by the pedestal 312. The enclosure 314 provides the outer body for the ALD reactor assembly. The substrate wafer 310 is loaded and unloaded on to the pedestal 312 through a load/unload port that is provided within the outer body 314, which is not shown in the diagram.

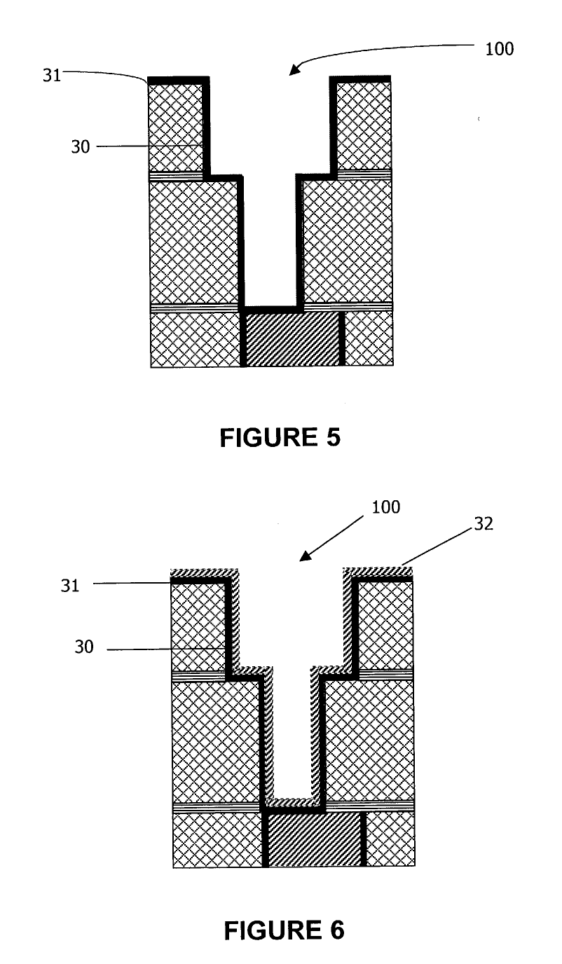

The ALD/CVD process sequence of the current invention begins with a detail description of the FIG. 5, which shows the magnified view of the cross section of the substrate wafer with dual damascene structure 100 already fabricated on its surface as the topmost layer. A highly conformal copper diffusion barrier layer 30 is deposited by employing an ALD process inside the dual damascene structure that is highly uniform in thickness. The copper diffusion barrier as deposited on the top surface of the substrate wafer during the process of deposition of the barrier 30 is specifically referred to by numeral 31, the intention of which will be soon clear. The thickness and uniformity of the layers 30 and 31 is substantially same. The copper diffusion barrier layer 30 can be in the form of a combination of one or more of the following materials, but not limited to: titanium nitride (TiN), tantalum nitride (TaN), tantalum (Ta), tungsten nitride (WNₓ), tungsten silicon nitride (WSiNₓ) or tungsten silicon nitride (WSiNₓ). Thickness of the copper diffusion barrier ranges between 3-12 nm with a nominal thickness of about 5 nm. ALD processes of deposition of a few representative thin film copper diffusion barrier materials are summarized below:

TiCl₄+NH₃→TiN+HCl (1)

TaCl₅+NH₃→TaN+HCl (2)

WF₆+(SiH₄+NH₃)→WSiNx+HF (3)

For sake of simplicity the equations of deposition reactions are not balanced.

FIG. 6 shows the magnified view of the cross section of the substrate wafer with dual damascene structure 100 already fabricated on its surface as the topmost layer, and subsequent to a perfectly conformal and highly uniform deposition of copper diffusion barrier layer 30, a part of copper diffusion barrier on the top substrate wafer surface 31 and a thin copper metal layer 32 by either an ALD or a CVD process.

The ALD processes of deposition of elemental copper films are known. These include, but are not limited to, reduction of cuprous chloride (CuCl) by H₂ between the temperatures of 300-350 deg. C. as published by Martensson et al. in Chemical Vapor Deposition, volume 3, No. 1, p. 45-50 (1997) and also by Martensson et al., in the Journal of Electrochemical Society, volume 145, No. 8, p. 2926-2931, August 1998 which describes ALD process of copper by reduction of Cu(II)-2,2,6,6-tetramethyl-3,5-heptanedionate [Cu(thd)₂] with H₂. Solanki and Pathangey described reduction of Cu(II)hfac₂, x H₂O, with H₂ gas and water and methanol, ethanol and aqueous formaldehyde as reducing agents at 300 deg. C. to produce high purity copper films with perfect conformality in high aspect ratio geometries, in Electrochemical and Solid State Letters, vol. 3, No. 10, p. 479-480, (2000). Recently, J. Huo et al. reported a copper ALD process at 260 deg. C in the Journal of Materials Research, volume 17, No. 9, p. 2394-2398, September 2002, with Cu(II)hfac₂, x H₂O, with isopropyl alcohol as a reducing agent. Martensson et al. summarized the deposition chemistry of copper from Cu(II)(hfac)₂ in hydrogen gas which is dissociatively adsorbed on the substrate surface, in the paper published in Chemical Vapor Deposition, volume 3, No. 1, page 45-50, 1997 as follows:

Surface+Cu(II)hfac₂→Cu(hfac)_{(ads)}+hfac_{(ads)} (4)

Cu(hfac)_{(ads)}+hfac_{(ads)}+H_{(ads)}→Cu+2 Hhfac (5)

Here, the subscript “ads” refers to the surface adsorbed species. The reaction temperature to achieve high purity copper layers in the reactions described in equations (4) and (5) is usually above 250 deg. C. Whereas, Laxmanan et al. in the paper published in the Journal of Electrochemical Society, volume 145, page 694-700, February 1998, showed the feasibility of deposition of high purity copper in direct RF plasma by atomic hydrogen (.H) and Cu(II)hfac₂ at temperatures below 190 deg. C. However, these researchers also found that high-energy electrons and ions can decompose the copper precursor in the gas phase. This resulted into high resistivity copper films, most probably due to inclusion of elements or fractions containing fluorine, carbon and/or oxygen. Hence, it is highly desirable to employ downstream hydrogen plasma (containing .H as the dominant species) along with Cu(II)hfac₂ or other suitable copper precursors such as Cu(II)(thd)₂, Cu(II)(hfac)₂, or chelate of copper with tri-methyl-vinyl-silane (tmvs) or any other volatile copper precursor, either in a pulsed or continuous mode to achieve an deposition process of copper at lower process temperatures without undesirable decomposition of the copper precursor thus obtaining high purity and high electrical conductivity copper films. The chemical reactions can be summarized as below:

Cu(II)(hfac)₂+2.H→Cu+2H⁺hfac (6)

2Cu(I)(hfac)L+2.H→Cu+Cu(II)(hfac)₂+2L→2Cu+2H⁺hfac+2L (7)

Here, L is a ligand such as TMVS. It is emphasized here that any particular reaction of vapor phase deposition process of copper, either in ALD mode or in CVD mode, does not limit the scope of the invention. An individual skilled in the art of plasma processes is generally knowledgeable about the downstream plasma processes in which the substrate is positioned far away from an active plasma zone such that active ions and high-energy electrons in the plasma are substantially eliminated by recombination.

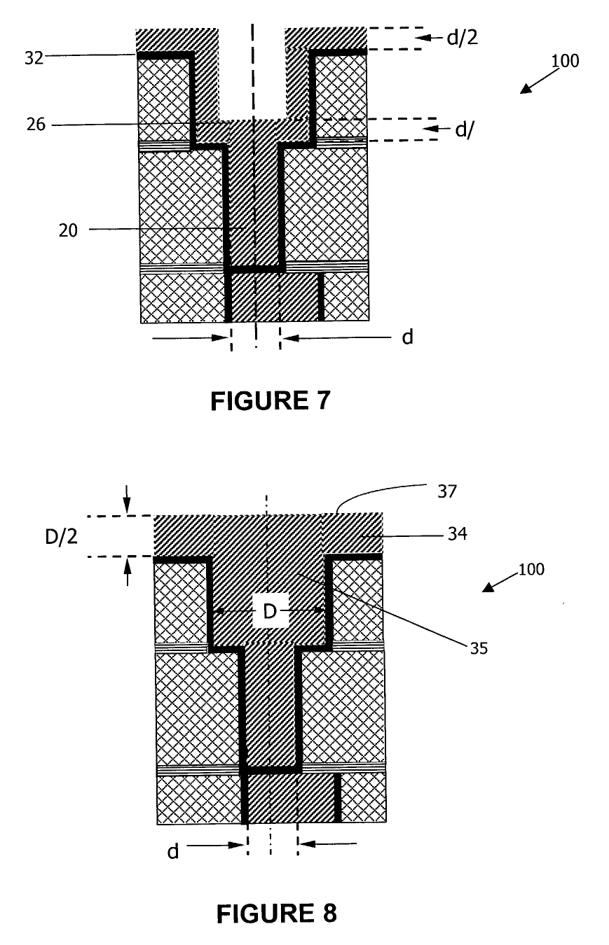

FIG. 7 shows results of the continuation of the copper ALD process that leads to complete filling of via 20 of the nominal dimension d (where d is the effective open via dimension after deposition of the diffusion barrier layer 30). As a result, copper thin film coating 32 with an effective thickness of d/2 is deposited in the trench 26 and also on top of the substrate wafer.

FIG. 8 illustrates the final step of copper ALD process to fill the dual damascene structure on top of the substrate wafer surface. Continuation of copper deposition process leads to complete filling of the trench 26 (which has an effective dimension D subsequent to deposition of the diffusion barrier 30). In the end a thin blanket film 34 of copper with effective thickness D/2 is deposited on the top surface of the substrate wafer. The final deliverable of the overall process sequence described above is a complete, void-free and conformal filling of the dual damascene structure by copper layer 35 in the trench along with an extremely flat top surface 37 without any pinhole or cavity on the top. In order to ensure that no cavity or pinhole is developed due to the conformal deposition by ALD on the top surface, several additional ALD sequences are employed to fill any such undesirable features. Selection of copper deposition process either by ALD technique or by CVD technique is mainly determined depending upon the physical dimensions of the etched dual damascene features. For larger features (via or trench), a high rate CVD process is usually employed to achieve practical and economical throughput. In order to achieve this result efficiently, without removing the substrate wafer from the processing reactor, a flexible ALD/CVD reactor is highly desirable.

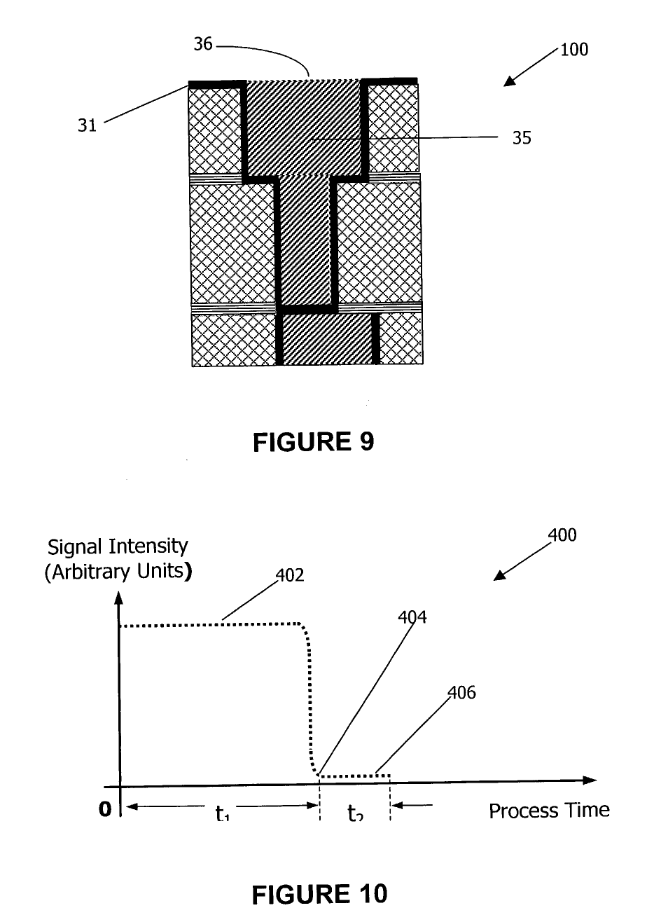

The substrate wafer is further processed within the same ALD/CVD reactor to remove the blanket copper thin film on the top surface of the substrate wafer as shown in FIG. 9. Subsequent to the complete removal of blanket copper thin film 34 (with a thickness substantially equal to D/2) by vapor phase process, a new patterned copper surface 36 of the filled copper layer 35 in the trench and the previously deposited diffusion barrier surface 31 are exposed. The vapor phase removal process may be run in a pulse mode (such as ALD) or in high rate continuous flow mode, e.g. in chemical vapor processing mode. The most plausible vapor phase chemical etching reaction to convert copper described below is well known in the art and are based on oxidation of the heated copper surface by a suitable oxidizer (oxidizing agent) such as oxygen, chlorine or bromine employed either in a molecular or radical state followed by the reaction of oxidized copper with one or more suitable chelating agents for example, but not limited to, H⁺hfac, H⁺thd, tmvs, to form a volatile copper chelate. The volatile copper chelate is removed from the vicinity of the copper surface under the combined action of vacuum and supplied heat energy. The pertinent chemical reactions for copper removal can be conveniently carried out at temperatures between 75 deg C. to 250 deg. C and reactor operating pressure between 50 mT to 5 Torr range. The pertinent chemical reactions are summarized below:

Cu(0)+X/X→CuX/Cu₂X (8)

CuX+2HL→Cu(II)L₂+2HX (9)

CuX+HL+HM→Cu(I)LM (10)

Here X is an oxidizer such as oxygen, chlorine, bromine, iodine or a mixture thereof. The oxidizer X can be in molecular form or in a highly reactive radical form denoted by symbol .X, (hereafter, a radical of a species will be denoted by such a symbol), which is conveniently generated by suitable plasma, whereas, HL and HM are the chelating agents for copper to form a volatile chelate. As an example, L=H⁺hfac, H⁺thd etc. and M=tmvs. The molecular species Cu(I)LM and Cu(II)L₂ are both volatile under the reactor operating conditions of pressure, temperature and flow. It is emphasized here that one or more vapor phase chelating agents HL and HM may be simultaneously employed to achieve the reactions as described in equations (9) and (10) to facilitate copper removal. Thus removing the oxidized copper exposes an underlying copper layer that is removed by employing the processes as described in equations (8)-(10) above.

During the process of copper deposition, the substrate wafer is maintained at a suitably high temperature in the range of 100-300 degrees C., whereas the reactor walls of the copper process reactor and its inner surfaces that are exposed to the reactive gaseous flows are maintained at a substantially lower temperature, in the range of 10-40 degrees C. in order to suppress back diffusion from reactor walls on to the substrate wafer and also to reduce the precursor consumption by surface chemical reactions.

Vapor phase removal of copper is achieved by adjusting the temperature of the inner surfaces of the copper process reactor along with the substrate wafer such that vapor phase copper removal reactions as described in equations (6) through (8) are initiated and accelerated to acceptable rate, which can be suitably achieved at temperatures below 250 degrees C.

FIG. 10 describes the detection of removal copper in the vapor phase by a suitable detecting instrument with process time. Such an instrument can be in the form of a residual gas analyzer, commonly known as RGA, which detects copper atoms in vapor phase by a mass spectrometry. The concentration of copper in vapor phase is proportional to the mass/charge signal magnitude for copper. A typical RGA graph 400 of the copper concentration with respect to time is shown in FIG. 10. During vapor phase copper removal process in which blanket copper film 34 is being removed, the detection signal magnitude is designated a value 402 that is almost constant with elapsed process time t₁. Subsequent to complete removal of the blanket film, a composite substrate wafer surface with a large fraction of the top diffusion barrier layer 30 and a very small fraction of gap filled copper layer surface 36 is exposed, which signifies the end of process and the copper detection signal drops significantly to its new magnitude 404. The removal process can be optionally run for time=t₂ beyond the end point time t₁, such that t₂<t₁ to ascertain complete removal of blanket copper layers from the top of the substrate wafer surface. A constant copper detection signal magnitude of 406 is established and the copper removal process is terminated at time t=t₁+t₂. Although, RGA has been used as an example of the copper detection and measurement system in the vapor phase, any other measurement technique such as optical emission spectroscopy is equally applicable and appropriate and should offer similar detection and measurement results with respect to the end-of-process.

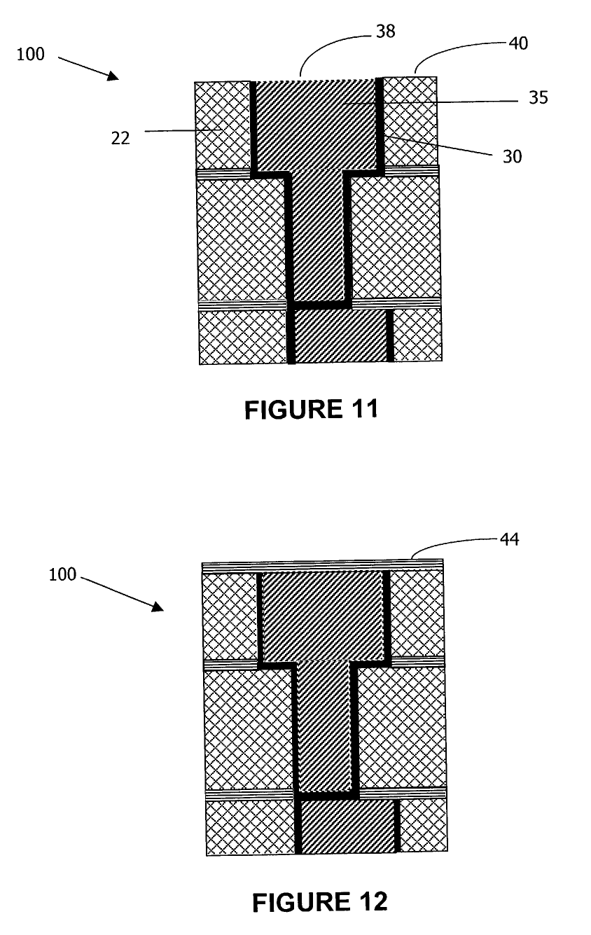

Referring to FIG. 11, the substrate wafer is treated for the removal of the copper diffusion barrier 31 from the top surface of the substrate wafer. A variety of vapor phase chemical schemes to achieve isotropic or anisotropic etching of various diffusion barriers such as Ta, TaN, WNₓ, WSiNₓ, are well known to an individual ordinarily skilled in the art. The most common and suitable being etching achieved by ions and radicals of halogen species such as fluorine, chlorine and bromine or a suitable combination thereof, in which the metallic constituent of the diffusion barrier material is converted in to a volatile product and removed from the vicinity of the surface. A few examples are in order such as (a) etching of tungsten and tungsten nitride using SF₆/Ar plasma as described by Reyes-Betanzo et al., in the Journal of Electrochemical Society, volume 149, page G179-G183, March 2002 (b) high rate tantalum etching in an atmospheric downstream plasma containing CF₄/O₂/He as described by Tu et al, in the Journal of Vacuum Science and Technology A, volume 18, page 2799-2805, November/December 2000 (c) etching of SiNx described by Kataoka et al., in the Journal of Electrochemical Society, volume 146, page 3435-3439, September 1999, and (d) the remote plasma processes employed to clean inner surfaces of the processing chamber as described in the U.S. Pat. No. 6,274,058 by Rajagopalan et al.

In summary, the chemical processes involved in removal of layer 31 by volatilization of its constituents can be summarized as shown below:

M/MNₓ/MSiNₓ+X/.X→MX_{y}+SiX_{z}+NX₃ (11)

Here, M=W, Ti, Ta etc. and X=F, Cl, Br and I.

The end point of the process can be suitably detected by following the procedure as described in 10 described above. Subsequent to the removal of top layer of the diffusion barrier 31, the surface 40 of the trench dielectric 22 and the top surface 38 of the filled trench 35 are exposed. During the removal process of barrier layer 31, the top surface 38 of copper filled trench 35 and the top surface 40 of dielectric are chemically affected and are halogenated, as described in equation (8), which is undesirable.

To eliminate chemically converted top copper surfaces 38 and 40, one or both of the following chemical schemes are employed: Chemical scheme (a): Since elemental copper is does not react with fluorine to form copper fluoride, (reference: Cotton, F. A. and Wilkinson, G., Basic Inorganic Chemistry, chapter 24, p. 413, John Wiley, New York, 1976) in case of F being employed to remove the copper diffusion barrier, substrate wafer surface that is composite in nature due to presence of surfaces 38 and 40, active hydrogen plasma comprising of H⁺ and/or .H radicals is employed to remove fluorine. The chemical reaction can be described as:

Surface−F+H⁺/.H→Surface−H+HF (12)

Chemical scheme (b): Helogenation or oxidation of metallic copper surface during the diffusion barrier 31 removal by halogens other than fluorine can lead to formation of copper halide (CuX₂/CuX, X=Cl, Br or I) on the surface of the copper layer 38, which is clearly undesirable. The chemical processes described in the equations (9) and (10) above to remove copper halide by chelation are suitably employed to remove halogenated copper.

Where the oxidizing agent employed is fluorine, subsequent to removal of the top layer of the copper diffusion barrier 31, the exposed surface of the dielectric layer 40 is treated by hydrogen radicals to remove any adsorbed fluorine in the barrier-processing reactor.

In case of etching chemistry employed to remove the copper diffusion barrier layer that consists of Cl, Br and I or any mixture thereof, copper surface is converted into respective chloride, bromide or iodide and must be treated again in accordance with the chemistries as outlined in the equations (5) and (6), in the barrier-processing reactor.

FIG. 12 illustrates the dual damascene structure subsequent to deposition of an etch stop or cap layer 44 on the top composite dual damascene surface comprising of surface 38 and surface 40. The composition of the blanket layer 44 is either SiNₓ or SiC. The chemical vapor deposition processes of deposition of SiNₓ or SiC layer are well known to an individual skilled in the art and do not require repetition. Also, the processes described in equations (1) through (12) can be performed either in a pulse mode or in a continuous flow mode.

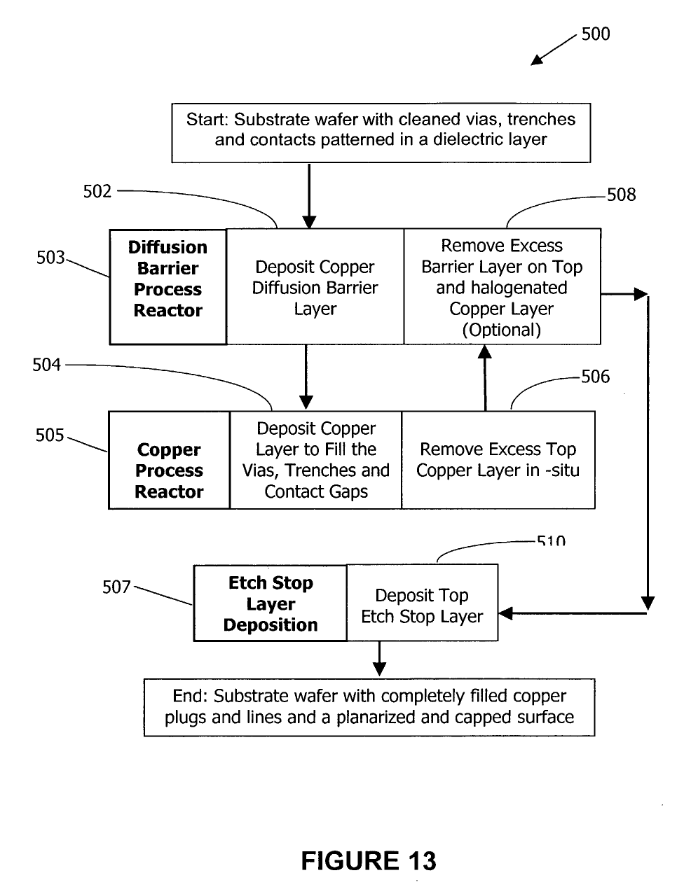

FIG. 13 illustrates the sequence scheme 500 of the substrate wafer during the deposition and etching processes as shown in FIGS. 5 through 9 and FIG. 11 and FIG. 12 to achieve one complete interconnect level of metallization with dual damascene structure. The substrate wafer is processed through three distinct processing reactors that are capable to operate either in pulsed mode or in a continuous mode of processing with varying degree of processing speed and precision. The substrate wafer with an etched dual damascene structure 100 as shown in FIG. 1 is the starting point of the process sequence. Copper diffusion barrier is deposited on the substrate wafer in step 502 in the diffusion barrier reactor 503. Next, copper fill is achieved in step 504 by transferring substrate to the copper process reactor 505. Further to this, in the same reactor 505, the top copper layer is removed in-situ, without removing the substrate wafer, to expose the copper—barrier composite surface. Next, the substrate wafer is transferred back to reactor 503 and process 508 of removal of the top layer of the diffusion barrier and process of removal of halogenated or reacted copper from diffusion barrier etching is performed. Subsequently, the substrate wafer is transported to the etch-stop or cap layer deposition reactor 507 to carry out the process 510 of deposition of the blanket layer on the dual damascene structure and the substrate is sent out for further processing, e.g. deposition of the next layer of dielectric layer.

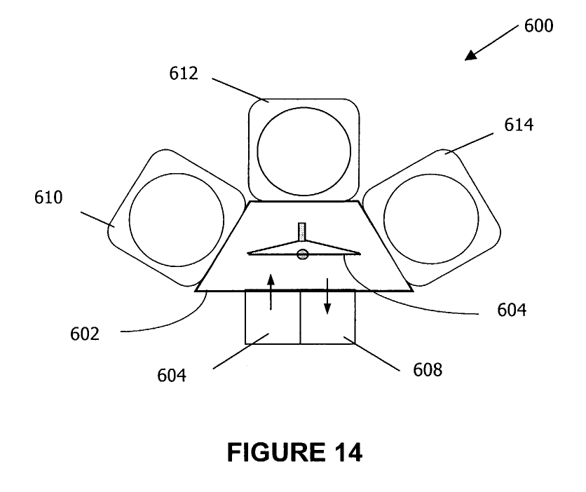

FIG. 14 illustrates schematic of the cluster tool system 600 frequently employed in the large scale manufacturing of advanced electronic devices. The cluster system 600 consists of a central substrate wafer exchanger module 602, a remotely controlled robot handler 604 situated within the wafer exchanger module 602, substrate wafer loading station 606, substrate wafer unloading station 608 and an ALP/CVP reactor 610 dedicated for barrier processing, an ALP/CVP reactor 612 dedicated for copper processing and an ALP/CVP reactor 614 dedicated for processing of the etch stop or cap layer 44, attached to the side walls of the central substrate wafer exchanger module 602 through remotely operated pneumatic gates (not shown). The substrate wafer is transported from one reactor to the other by the remotely controlled robot handler 604 through the remotely operated pneumatic gates (not shown) interposed between the central substrate wafer exchanger 602 and each of the substrate wafer processing reactors. In practice, the cluster tools systems may have more than three reactors attached to the central substrate wafer exchanger module for high efficiency operation. In such a case, the process that takes longer time as compared to the processes being run in other reactors, will be assigned multiple reactors that perform the same function and operate in parallel. As an example, it is estimated that copper processing is longer recipe as compared to diffusion barrier processing, merely due to the thickness of the film to be deposited and removed, then there will be multiple copper processing reactors in such a system.

### EXAMPLE

Gap Fill and Etch-Back of Tungsten on Ti—TiN Barrier:

Gap fill of elemental tungsten in an ALD mode can be achieved by employing either silyl free radicals (.SiH₃) or atomic hydrogen (.H) or with a mixture thereof, generated in a downstream mode of an active plasma, with tungsten hexafluoride (WF₆) as a tungsten source in an ALD or CVD mode as described by the inventors in the U.S. patent application Ser. No. 10/288,345 filed Nov. 4^{th}, 2002 and in the US Patent Application filed on February 21st, 2003 with an attorney docket No. 2774P. Chemical reactions for deposition of tungsten metal can be described as follows:

WF₆+.SiH₃/.H→W+SiF₄/SiH₂F₂/HF (13)

WF₆+.H→W+HF (14)

The contact hole etched in the gate dielectric is first coated by a tungsten diffusion barrier layer such as titanium—titanium nitride (Ti—TiN), composite barrier, which is also deposited by an ALD process. An ALD process for deposition of TiN barrier is described in equation (1). The ALD process chemistry for metallic titanium layer can be suitably developed by employing titanium halide (TiX₄, X=Cl, Br, I) and hydrogen free radicals (.H) as follows:

TiX₄+.H→Ti+4HX (15)

The contact hole is first completely filled by tungsten and excess tungsten along with the titanium nitride layer on the top planar surface is etched back in isotropic mode by employing halogen free radicals (.X, such that X=F, O, Cl, Br) generated by a suitable plasma source in-situ as described in equation (7). The top tungsten layer on the substrate wafer is etched back and simultaneously the undesirable tungsten deposition on the inner walls of the chamber is also cleaned. Such a process sequence allows the integration of process steps and operation of the substrate processing reactors for barrier processing (in this case Ti—TiN) and metal processing—tungsten deposition to operate in quasi-clean mode.

Thus, it has been shown that the present invention provides a method of manufacturing a gap-filled structure of a semiconductor device, which is eliminates the need for electrochemical or electroless deposition, as well as for subsequent planarization, e.g., by means of CMP. The method of the invention is carried out entirely in a gaseous phase, thus simplifying the construction of the process equipment and eliminating additional operations such as secondary cleaning with deionized water, etc. The method of the invention significantly reduces the amount of waste products. Although the invention has been shown and described with reference to specific embodiments, it is understood that these embodiments should not be construed as limiting the areas of application of the invention and that any changes and modifications are possible, provided these changes and modifications do not depart from the scope of the attached patent claims. For example, other conductive materials such as aluminum and carbon can be used in addition to copper and tungsten. The barrier layer may comprise carbides, nitride, and suicides of metals such as Zr, Hf, Nb and Mo. More than two or three working chambers can be combined into a cluster tool.

What is claimed is:

1. A method of filling a recess in a surface of an object comprising the steps of:
providing an atomic layer processing apparatus having a working chamber, at least a first chemical supply unit for the supply of a first chemical agent and a second chemical supply unit for the supply of a second chemical agent into said working chamber, said first chemical agent and said second chemical agent reacting with each other to produce a deposition material;
supplying said first chemical agent and said second chemical agent to said working chamber after said object is placed into said atomic layer processing apparatus;
causing a reaction between said first chemical agent and said second chemical agent for producing reaction products that contains said deposition material;
evacuating said working chamber for removing said reaction products except said deposition material;
depositing said deposition material into said recess by a process selected from atomic layer deposition and chemical vapor deposition for decomposing at least one of said first chemical agent and said second chemical agent in order to deposit said deposition material in the form of a deposited layer of a uniform thickness onto said surface and into said recess;
filling said recess by a process selected from continuously depositing said deposition material by said chemical vapor deposition and by repeating said step of depositing said deposition material by said atomic layer deposition process until said recess is completely filled, said deposited layer on said top surface having a thickness being substantially equal to half of said width of said recess.

2. The method of claim 1, further comprising the step of removing said deposited layer from said surface until said surface is exposed, said step of depositing and said step of removing being carried out in said atomic layer processing apparatus.

3. The method of claim 2, wherein said atomic layer processing apparatus is a first atomic layer processing apparatus, said object is a semiconductor device with a patterned dielectric layer on a substrate, said dielectric layer has a top surface; said gap is completely filled with a conductive material, said gap having a width, said deposition material comprising said conductive material, said reaction causing decomposition of said at least one of said first chemical agent and said at least second chemical agent.

4. The method of claim 3, further comprising the following steps which are carried out prior to all steps of said claim 3:
providing a second atomic layer processing apparatus for processing a barrier-layer made from a barrier-layer material resistant to diffusion of said conductive material into said patterned dielectric layer, said second atomic layer processing apparatus having a barrier-layer processing chamber, at least a first barrier-layer chemical supply unit for the supply of a first barrier-layer chemical agent, and a second barrier-layer chemical supply unit for the supply of a second barrier-layer chemical agent into said barrier-layer processing chamber, said barrier layer having a barrier-layer thickness;
placing said substrate with said patterned dielectric layer into said second atomic layer processing apparatus for processing a barrier-layer;
supplying said first barrier-layer chemical agent and said second barrier-layer chemical agent to said barrier-layer processing chamber, causing a chemical reaction between said first barrier-layer chemical agent and said second barrier-layer chemical agent on the surface of said patterned dielectric layer for forming said barrier layer composed of a barrier layer material by atomic layer deposition;
repeating said step of forming said barrier layer until said barrier-layer thickness is achieved;
placing said substrate with said barrier layer on said pattern dielectric layer into said first atomic layer processing apparatus;
carrying out all steps of claim 3;
placing said substrate into said second atomic layer processing apparatus; and
removing said barrier layer from said top surface.

5. The method of claim 4, further comprising the steps of:
providing a third layer processing apparatus for processing a cap layer made from a cap layer material, said third layer processing apparatus having a cap layer processing chamber, at least a first cap layer chemical supply unit for the supply of a first cap layer chemical agent, and a second cap layer chemical supply unit for the supply of a second cap layer chemical agent into said cap layer processing chamber;
placing said substrate into said third layer processing apparatus after completion of said steps of claim 4 for forming said cap layer; and
supplying said first cap layer chemical agent and said second cap layer chemical agent to said cap layer processing chamber, causing a chemical reaction between said first cap layer chemical agent and said second cap layer chemical agent on said top surface of said dielectric layer, on said conductive material, and on said barrier layer.

6. The method of claim 5, comprising the steps of:
combining said first atomic layer processing apparatus, said second atomic layer processing apparatus, and said third atomic layer processing apparatus into a cluster machine provided with means for transferring said substrate between said first atomic layer processing apparatus, said second atomic layer processing apparatus, and said third atomic layer processing apparatus, and
performing said steps of claims 3, 4, and 5 with the use of said cluster machine, while performing said steps of placing said substrate into said first atomic layer processing apparatus, said second atomic layer processing apparatus, and said third atomic layer processing apparatus with the use of said means for transferring.

7. The method of claim 3, wherein said conductive material is selected from the group comprising copper and tungsten, said first chemical agent being selected for copper from a group comprising CuCl, Cu(II)(Hfac)₂, Cu(I)(hfac)tmvs, Cu(II)(thd)₂, for tungsten from a group comprising of WF₆, WCl₆, W(CO)₆, and said second chemical agent being selected for copper from the group comprising of H₂, .H, and for tungsten from the group comprising H₂, .H, .SiH₃.

8. The method of claim 4, wherein said conductive material is selected from the group comprising copper and tungsten, said first chemical agent being selected for copper from the group comprising of CuCl, Cu(II)(hfac)₂, Cu(I)(hfac)tmvs, Cu(II)((thd)₂, for tungsten from the group comprising of WF₆, WCl₆, W(CO)₆, said second chemical agent being selected for copper from the group comprising H₂, .H, and for tungsten from the group comprising of H₂, .H, .SiH₃; said first barrier-layer chemical agent being selected from the group comprising of WF₆, TiCl₄, TiBr₄, Til₄,TaCl₅; and said second barrier-layer chemical agent being selected from the group comprising of SiH₄, NH₃, CH₄, .NH₂, .CH₃, H₂, .H.

9. The method of claim 5, wherein said conductive material is copper, said first chemical agent being selected from the group comprising of CuCl, Cu(II)(hfac)₂, Cu(I)(hfac)tmvs, Cu(II)(thd)₂, said second chemical agent being selected from the group comprising of H₂, .H; said first barrier-layer chemical agent being selected from the group comprising of WF₆, TiCl₄, TiBr₄, Til₄,TaCl₅; said second barrier-layer chemical agent being selected from the group comprising of SiH₄, NH₃, CH₄, .NH₂, .CH₃, H₂, .H; and said cap layer chemical agent being selected from the group comprising of SiH₄, NH₃, CH₄, .NH₂, .CH₃, H₂, .H.

10. The method of claim 4, comprising the steps of:
combining said first atomic layer processing apparatus and said second atomic layer processing apparatus into a cluster machine provided with means for transferring said substrate between said first atomic layer processing apparatus and said second atomic layer processing apparatus; and
performing said steps of claims 3 and 4 with the use of said cluster machine, while performing said steps of placing said substrate into said first atomic layer processing apparatus and said second atomic layer processing apparatus with the use of said means for transferring.

11. The method of claim 3, wherein said step of removal further comprises the steps of:
purging said working chamber of said second atomic layer processing apparatus after completing said step of filling said gap with said conductive material;
supplying a third chemical agent to said working chamber of said first atomic layer processing apparatus;
causing a reaction between said third chemical agent and said conductive material for producing an intermediate product of reaction on said conducive material, said intermediate product containing said conductive material;
supplying a fourth chemical agent to said working chamber of said first atomic layer processing apparatus;
causing a reaction between said fourth chemical agent and said intermediate product for producing a volatile product that contains said conductive material; and
removing said volatile material from said working chamber.

12. The method of claim 11, wherein said conductive material is selected from the group comprsing of copper and tungsten, said third chemical agent being selected for copper from the group comprising of O₂, Cl₂, Br₂, .O, .Cl, .Br, .OH, and for tungsten from .F, .Cl, .Br, and said fourth chemical agent being selected for copper from the group comprising of H⁺hfac, H⁺thd, tmvs.

13. The method of claim 4, wherein said step of removing said barrier layer from said top surface comprises the steps of:
purging said working chamber of said second atomic layer processing apparatus;
supplying at least one third barrier-layer chemical agent to said working chamber of said second atomic layer processing apparatus;
causing a reaction between said third barrier-layer chemical agent and said barrier layer for producing volatile products of reaction that contains said barrier-layer material; and
removing said volatile products from said working chamber of said second atomic layer processing apparatus.

14. The method of claim 13, wherein said third barrier layer chemical agent being selected from the group comprising of O₂, Cl₂, Br₂, .O, .Cl, .Br, and .F.
